(19) United States
(12) Patent Application Publication
(10) Pub. No.: US 2016/0043199 A1
(43) Pub. Date: Feb. 11, 2016

(54) METHOD OF MANUFACTURING SEMICONDUCTOR DEVICE

(71) Applicant: Kabushiki Kaisha Toshiba, Tokyo (JP)

(72) Inventors: Yasuto Sumi, Nonoichi Ishikawa (JP); Hiroaki Yamashita, Hakusan Ishikawa (JP)

(21) Appl. No.: 14/626,641

(22) Filed: Feb. 19, 2015

(30) Foreign Application Priority Data
Aug. 7, 2014 (JP) 2014-161844

(51) Int. Cl. H01L 29/66; H01L 29/06

(52) U.S. Cl. CPC H01L 29/66712; H01L 29/0634

(57) ABSTRACT

According to a method of manufacturing a semiconductor device of embodiments, a first trench is formed in a first semiconductor layer of a first conductivity type, a second semiconductor layer of a second conductivity type is formed in the first trench by using an epitaxial growth method, a second trench is formed in the second semiconductor layer, the second trench having a smaller depth than the first trench, a third semiconductor layer of the second conductivity type is formed in the second trench by using the epitaxial growth method, a gate insulating film is formed on the third semiconductor layer, a gate electrode is formed on the gate insulating film, and a first semiconductor region of the first conductivity type is formed in the third semiconductor layer.

### CROSS-REFERENCE TO RELATED APPLICATION

This application is based upon and claims the benefit of priority from Japanese Patent Application No. 2014-161844, filed on Aug. 7, 2014, the entire contents of which are incorporated herein by reference.

### FIELD

Embodiments described herein relate generally to methods of manufacturing semiconductor devices.

### BACKGROUND

Semiconductor devices compatibly achieving high breakdown voltage and low on-resistance include a vertical metal oxide semiconductor field effect transistor (MOSFET) that has a superjunction structure (hereinafter also referred to as an “SJ structure”) in which a p-type (or an n-type) semiconductor layer is buried in an n-type (or a p-type) semiconductor layer to arrange an n-type region and a p-type region alternately. The SJ structure achieves high breakdown voltage by equalizing the amounts between n-type impurities included in the n-type region and p-type impurities included in the p-type region to create a pseudo-nondoped region. At the same time, low on-resistance is achieved by passing an electric current in a region of higher impurity concentration.

After the SJ structure is formed, base and source regions of the MOSFET are formed by ion implantation of impurities and heat treatment. In performing the heat treatment, impurities in the n-type region and p-type region of the SJ structure are thermally diffused as well. This causes a change in impurity profile of the SJ structure, which may lead to instability in breakdown voltage.

### BRIEF DESCRIPTION OF THE DRAWINGS

FIG. 1 is a schematic cross-sectional view of a semiconductor device to be manufactured by a method of manufacturing a semiconductor device according to a first embodiment.

FIG. 2 is a schematic cross-sectional view of the semiconductor device in a manufacturing process of the semiconductor device manufacturing method according to the first embodiment.

FIG. 3 is a schematic cross-sectional view of the semiconductor device in a manufacturing process of the semiconductor device manufacturing method according to the first embodiment.

FIG. 4 is a schematic cross-sectional view of the semiconductor device in a manufacturing process of the semiconductor device manufacturing method according to the first embodiment.

FIG. 5 is a schematic cross-sectional view of the semiconductor device in a manufacturing process of the semiconductor device manufacturing method according to the first embodiment.

FIG. 6 is a schematic cross-sectional view of the semiconductor device in a manufacturing process of the semiconductor device manufacturing method according to the first embodiment.

FIG. 7 is a schematic cross-sectional view of a semiconductor device to be manufactured by a method of manufacturing a semiconductor device according to a second embodiment.

FIG. 8 is a schematic cross-sectional view of a semiconductor device to be manufactured by a method of manufacturing a semiconductor device according to a third embodiment.

FIG. 9 is a schematic cross-sectional view of a semiconductor device to be manufactured by a method of manufacturing a semiconductor device according to a fourth embodiment.

### DETAILED DESCRIPTION

According to a method of manufacturing a semiconductor device of embodiments, a first trench is formed in a first semiconductor layer of a first conductivity type, a second semiconductor layer of a second conductivity type is formed in the first trench by using an epitaxial growth method, a second trench is formed in the second semiconductor layer, the second trench having a smaller depth than the first trench, a third semiconductor layer of the second conductivity type is formed in the second trench by using the epitaxial growth method, a gate insulating film is formed on the third semiconductor layer, a gate electrode is formed on the gate insulating film, and a first semiconductor region of the first conductivity type is formed in the third semiconductor layer.

Embodiments of the present invention are described below with reference to the drawings. It is to be noted that in the following description, the same members and portions are assigned the same reference numerals, and description is not given where appropriate of the members and portions described once.

The indications of n⁺-type, n-type, and n⁻-type herein mean that n-type impurity concentration is lower in this order. Likewise, the indications of p⁺-type, p-type, and p⁻-type mean that p-type impurity concentration is lower in this order.

### First Embodiment

A method of manufacturing a semiconductor device according to a first embodiment includes: forming a first trench in a first semiconductor layer of a first conductivity type; forming a second semiconductor layer of a second conductivity type in the first trench by using an epitaxial growth method; forming a second trench in the second semiconductor layer, the second trench having a smaller depth than the first trench; forming a third semiconductor layer of the second conductivity type in the second trench by using the epitaxial growth method; forming a gate insulating film on the third semiconductor layer; forming a gate electrode on the gate insulating film; and forming a first semiconductor region of the first conductivity type in the third semiconductor layer.

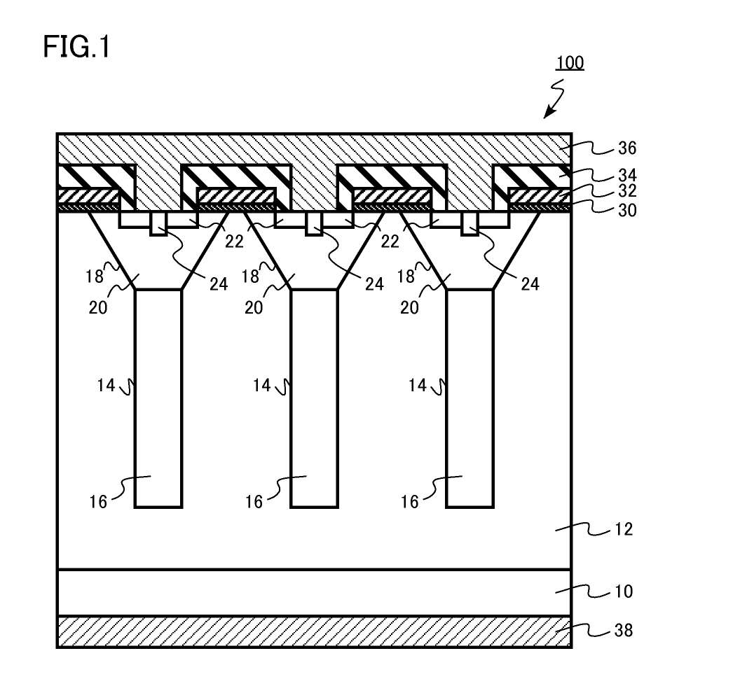

FIG. 1 is a schematic cross-sectional view of a semiconductor device to be manufactured by a method of manufacturing a semiconductor device according to the first embodiment. A semiconductor device 100 of the first embodiment is a vertical MOSFET having a superjunction structure. Description is given below by way of an example in which a first conductivity type is n-type and a second conductivity type is p-type.

The semiconductor device (MOSFET) 100 of the present embodiment includes an n-type drift region (first semiconductor layer) 12 on an n⁺-type substrate 10. The substrate 10 and the drift region 12 are, for example, monocrystalline silicon containing n-type impurities. The n-type impurity concentration of the drift region 12 is lower than the n-type impurity concentration of the substrate 10. The n-type impurities are, for example, phosphorus (P) or arsenic (As).

The n⁺-type substrate 10 functions as a drain region of the MOSFET 100.

P-type regions (second semiconductor layers) 16 are arranged in a plurality of first trenches 14 in the drift region 12. The p-type regions 16 are, for example, monocrystalline silicon containing p-type impurities. The p-type impurities are, for example, boron (B).

In the semiconductor device 100 of the present embodiment, the plurality of p-type regions 16 is arranged alternatively with the n-type drift region 12 to form an SJ structure. The p-type regions 16 are so-called p-type pillar regions, and the drift region 12 is a so-called n-type pillar region.

The p-type regions 16 and the n-type drift region 12 that are arranged alternately form pseudo, almost nondoped regions. Thus, high breakdown voltage is achieved.

P-type base regions (third semiconductor layers) 20 are arranged above the p-type regions 16 in contact with the p-type regions 16. The base regions 20 are positioned in second trenches 18. Further, a plurality of n⁺-type source regions (first semiconductor regions) 22 is arranged on the surfaces of the p-type base regions 20. For example, two source regions 22 are arranged on the surface of each base region 20. Further, p⁺-type base contact regions 24 are arranged on the surfaces of the base regions 20 such that each p⁺-type base contact region 24 is located between adjacent source regions 22.

The n-type impurity concentration of the source regions 22 is higher than the n-type impurity concentration of the drift region 12. Further, the p-type impurity concentration of the base contact regions 24 is higher than the p-type impurity concentration of the p-type regions 16 and the base regions 20.

Gate insulating films 30 are arranged on the base regions 20 that are interposed between the drift region 12 and the source regions 22. Further, gate electrodes 32 are arranged on the gate insulating films 30. Interlayer dielectrics 34 are arranged over the gate electrodes 32.

The gate insulating films 30 are, for example, silicon oxide films. The gate electrodes 32 are, for example, polycrystalline silicon containing n-type impurities. Further, the interlayer dielectrics 34 are, for example, silicon oxide films.

The base regions 20 immediately below the gate insulating films 30 function as channel regions of the MOSFET 100.

A source electrode 36 is disposed over the source regions 22 and the base contact regions 24. The source electrode 36 is, for example, a metal containing aluminum (Al).

A drain electrode 38 is disposed over the surface of the n-type substrate 10 opposite the drift region 12 . The drain electrode 38 is, for example, a metal containing aluminum (Al).

In the MOSFET 100, the p-type impurity concentration of the p-type base regions (third semiconductor layers) 20 is desirably lower than the p-type impurity concentration of the p-type regions 16. Especially, in case where the second trenches 18 have a wider width than the first trenches 14 and the base regions 20 have a wider width than the p-type regions 16, the same p-type impurity concentration may break the balance in charge between the p-type impurities in the base regions 20 and the n-type impurities in drift region 12 that are located between the base regions 20, which may lead to lowering of breakdown voltage. Further, the p-type impurity concentration of the base regions 20 is desirably lower from the viewpoint of controllability of a threshold voltage also in case where ion implantation for threshold voltage adjustment is performed to adjust the threshold voltage for the MOSFET 100.

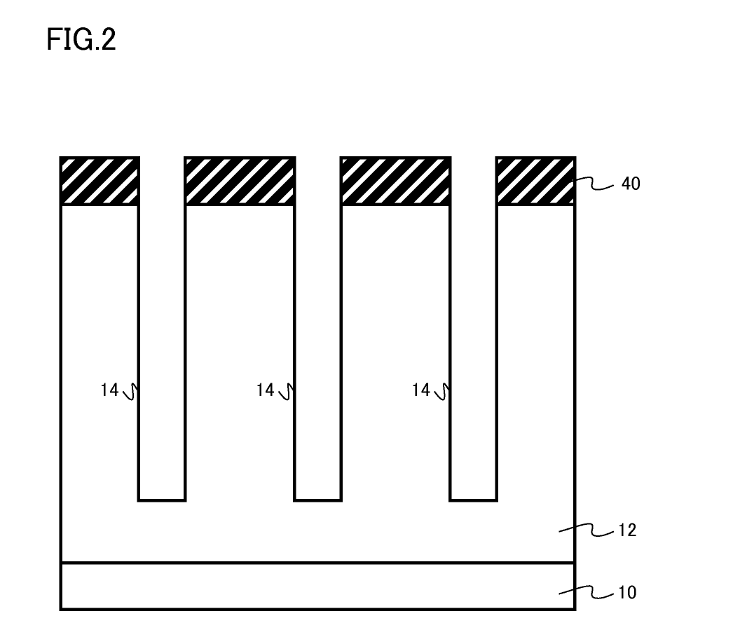

Next, description is given of a method of manufacturing a semiconductor device according to the present embodiment. FIGS. 2 to 6 are schematic cross-sectional views of a semiconductor device in manufacturing processes of the semiconductor device manufacturing method according to the present embodiment.

An n-type drift region (first semiconductor layer) 12 of monocrystalline silicon containing n-type impurities is formed on a surface of an n⁺-type substrate 10 of monocrystalline silicon containing n-type impurities by an epitaxial growth method.

Next, for example, a mask material 40 of a silicon oxide film is formed on the surface of the drift region 12. The mask material 40 is, for example, formed through film deposition by way of chemical vapor deposition (CVD), lithography, and reactive ion etching (RIE).

Next, the drift region 12 is etched with the mask material 40 used as a mask, so as to form first trenches 14 (FIG. 2). The etching is performed, for example, by RIE.

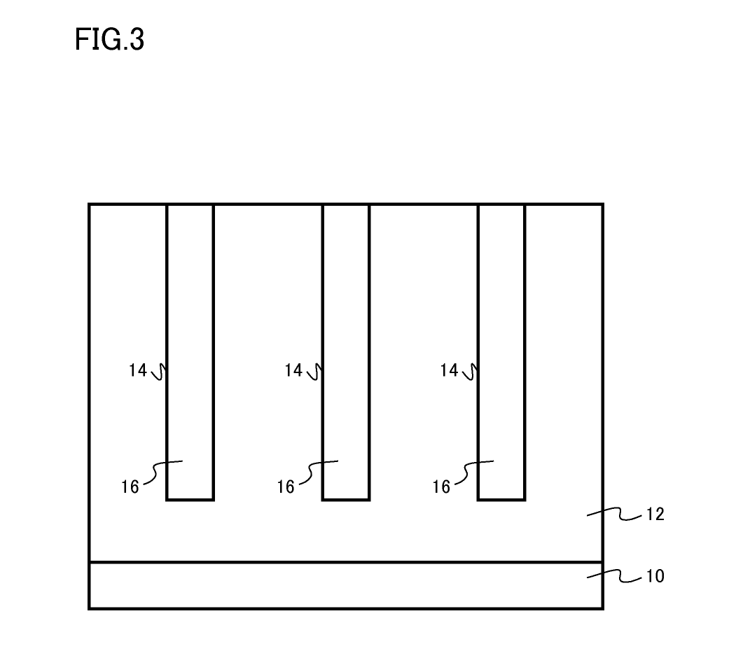

Next, the mask material 40 is removed, for example, by wet etching. Then, p-type regions (second semiconductor layers) 16 containing p-type impurities are formed in the first trenches 14 by the epitaxial growth method. The p-type regions 16 are, for example, monocrystalline silicon containing p-type impurities. After the p-type regions 16 are formed, the surfaces of the p-type regions 16 are polished by chemical mechanical polishing (CMP) to expose the drift region 12 (FIG. 3).

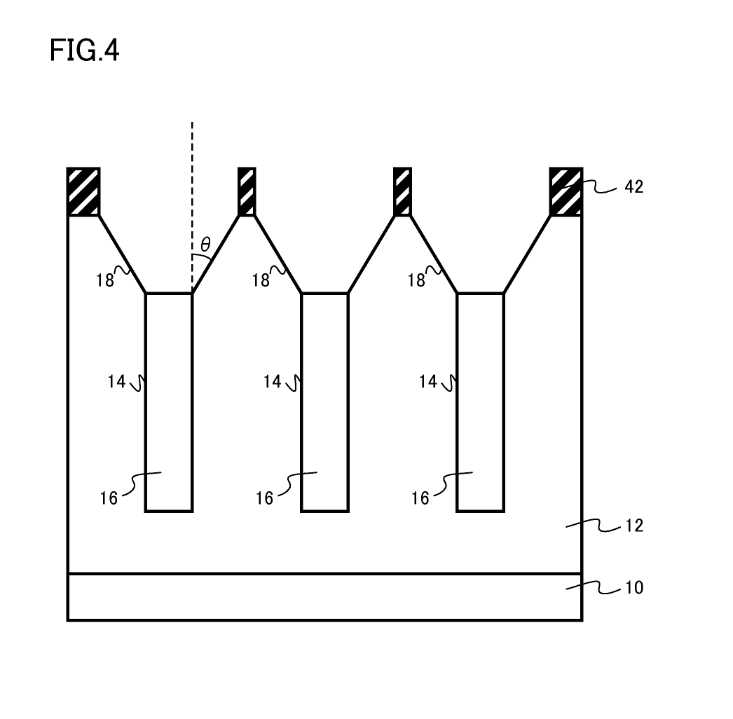

Next, regions including the p-type regions (second semiconductor layers) 16 are etched with a mask material 42 used as a mask, so as to form second trenches 18 having a shallower depth than the first trenches 14 (FIG. 4). The etching is performed, for example, by RIE. The second trenches 18 have a depth of, for example, 2 μm to 4 μm.

The second trenches 18 desirably have a wider width than the first trenches 14 in order to provide larger margins for accommodating misalignment in processing.

The side surfaces of the second trenches 18 are inclined at an inclination angle (θ in FIG. 4) with respect to the film thickness direction of the drift region (first semiconductor layer) 12, and the inclination angle θ is desirably larger than the inclination angle at which the side surfaces of the first trenches 14 are inclined with respect to the film thickness direction of the drift region (first semiconductor layer) 12. The larger inclination angle of the second trenches 18 allows for, for example, moderation of concentration of electric fields at corners of the bottom surfaces of the second trenches 18 and improvement in breakdown voltage of the MOSFET 100. The side surfaces of the second trenches 18 are desirably inclined at the inclination angle (θ in FIG. 4) of 5 degrees to 15 degrees with respect to the film thickness direction of the drift region (first semiconductor layer) 12.

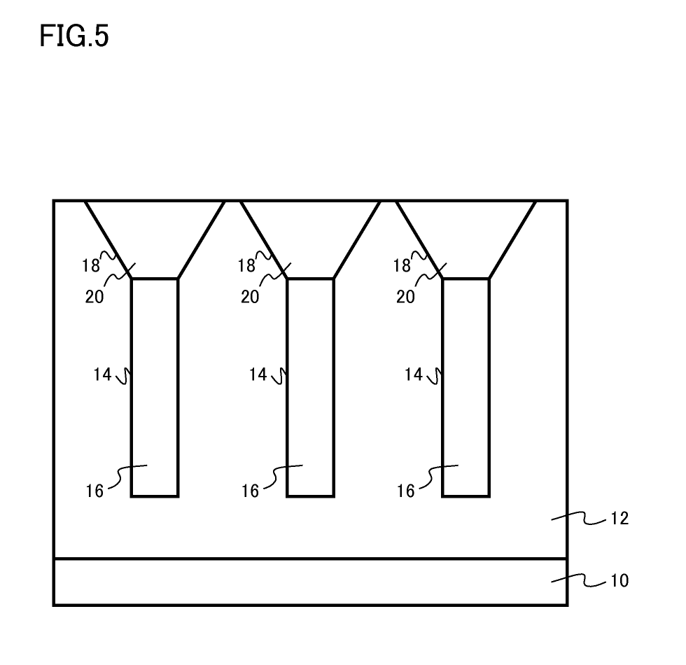

Next, the mask material 42 is removed, for example, by wet etching. Then, p-type base regions (third semiconductor layers) 20 containing p-type impurities are formed in the second trenches 18 by the epitaxial growth method. The base regions 20 are, for example, monocrystalline silicon containing p-type impurities. After the base regions 20 are formed, the surfaces of the base regions 20 are polished by CMP to expose the drift region 12 (FIG. 5). The p-type impurity concentration of the p-type base regions (third semiconductor layers) 20 is desirably lower than the p-type impurity concentration of the p-type regions 16.

Next, gate insulating films 30 are formed, for example, by thermal oxidation. After that, gate electrodes 32 are formed on the gate insulating films 30 by a known manufacturing method.

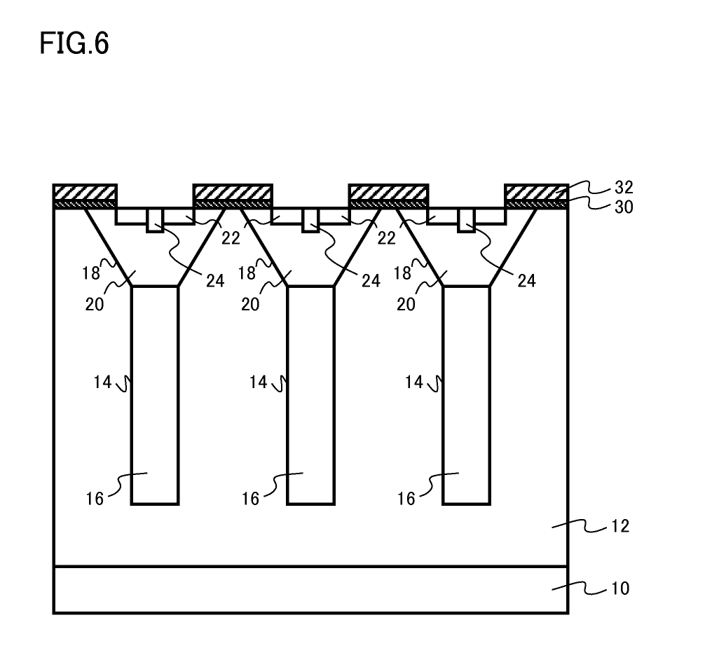

Next, n⁺-type source regions (first semiconductor regions) 22 with a shallower depth than the base regions 20 are formed in the base regions 20, for example, by ion doping of impurities and annealing for activating the impurities. Further, p⁺-type base contact regions 24 with a shallower depth than the base regions 20 are formed in the base regions 20, for example, by ion implantation of impurities and annealing for activating the impurities (FIG. 6).

After that, interlayer dielectrics 34, a source electrode 36, and a drain electrode 38 are formed by known manufacturing methods, such that the MOSFET 100 depicted in FIG. 1 is completed.

Next, description is given of functions and effects of the method of manufacturing the semiconductor device according to the present embodiment.

In the SJ structure, n-type regions and p-type regions are arranged alternately and the amount of n-type impurities included in the n-type regions is equalized to the amount of p-type impurities included in the p-type regions, such that pseudo nondoped regions are created, thus achieving high breakdown voltage. At the same time, an electric current is passed through regions of higher impurity concentration, such that lower on-resistance is achieved.

If heat treatment is performed at a high temperature or for a long period of time after the SJ structure is formed, the heat treatment causes thermal diffusion of the n-type impurities in the n-type regions and the p-type impurities in the p-type regions, hence change in impurity profile. As a result of the change in profile, breakdown voltage may be reduced, or the controllability of breakdown voltage may be lowered. Further, on-resistance may be increased, or the controllability of on-resistance may be lowered.

In case where the formation of the base regions of the MOSFET is performed by ion implantation and annealing, heat treatment is performed at a relatively higher temperature or for a relatively longer period of time, since the base regions have a deeper depth than, for example, the source regions. This magnifies change in impurity profile during the heat treatment for forming the base regions.

According to the method of manufacturing the MOSFET 100 of the present embodiment, the p-type base regions 20 are formed by the formation of the second trenches 18 and burying of the base regions 20 byway of epitaxial growth. Hence, the thermal diffusion of the n-type impurities and p-type impurities comprising the SJ structure is suppressed. Thus, reduction of breakdown voltage is suppressed, and the controllability of breakdown voltage is improved. Further, increase in on-resistance is suppressed, and the controllability of on-resistance is improved.

Moreover, since the p-type base regions 20 are formed not by ion implantation but by epitaxial growth, crystal defect is reduced in the p-type base regions 20. Hence, a MOSFET with reduced leakage current is achieved.

### Second Embodiment

A method of manufacturing a semiconductor device according to a second embodiment is the same as that of the first embodiment except that the second trenches are formed in a U shape. Hence, the details overlapping those of the first embodiment are not described redundantly.

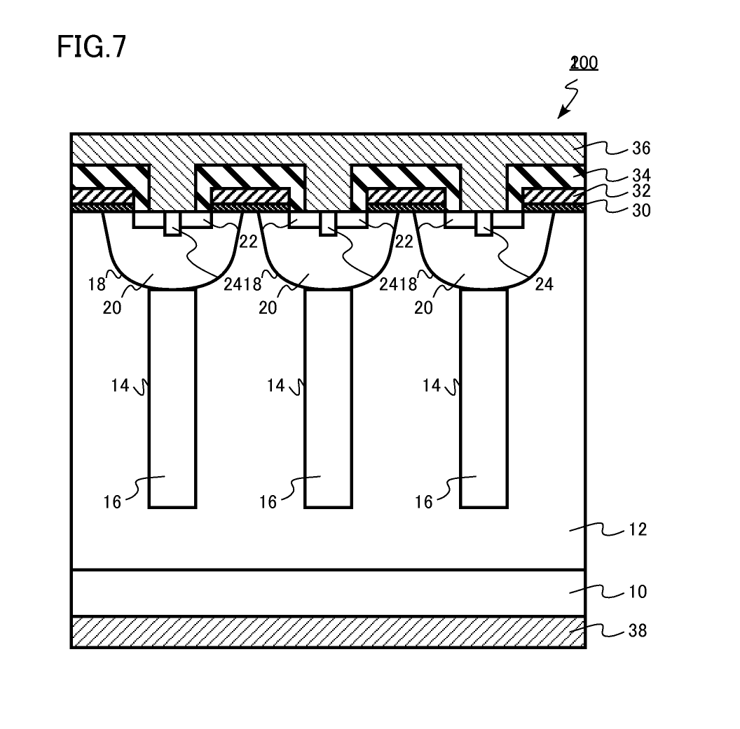

FIG. 7 is a schematic cross-sectional view of a semiconductor device to be manufactured by the semiconductor device manufacturing method according to the second embodiment. According to the semiconductor device manufacturing method according to the second embodiment, in forming second trenches 18, etching is performed such that the trenches have a U shape.

According to the method of manufacturing a MOSFET 200 of the second embodiment, the same effects as those of the first embodiment are obtained. Moreover, as depicted in FIG. 7, the second trenches 18 are U-shaped, such that the source regions 22 and the drift region 12 are at a larger distance at depths as compared to those of the first embodiment. Hence, breakdown voltage is increased, for example, between the source regions 22 and the drift region 12.

### Third Embodiment

A method of manufacturing a semiconductor device according to a third embodiment is the same as that of the first embodiment except that the ion implantation process for threshold voltage adjustment is further included. Hence, the details overlapping those of the first embodiment are not described redundantly.

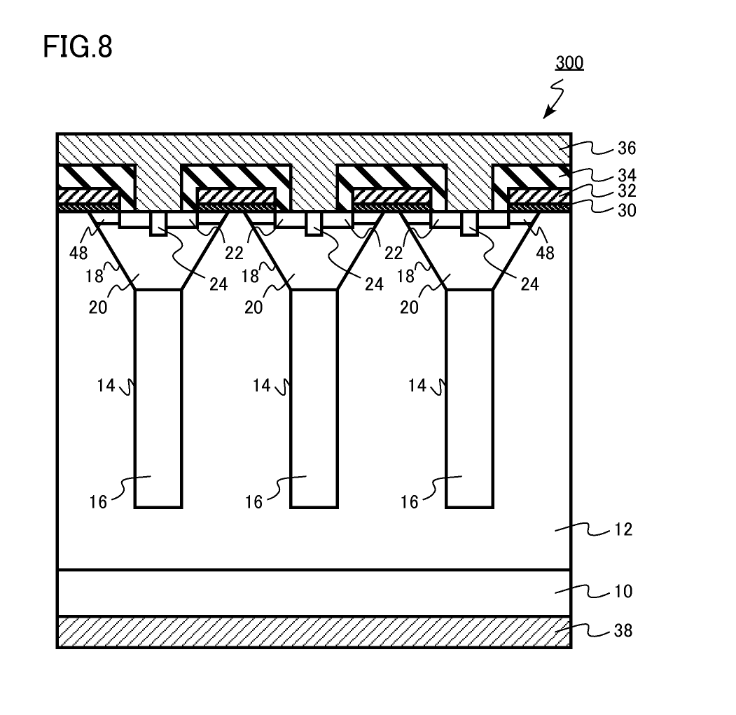

FIG. 8 is a schematic cross-sectional view of a semiconductor device to be manufactured by the semiconductor device manufacturing method according to the third embodiment.

A MOSFET 300 of the third embodiment includes p⁻-type channel regions (second semiconductor regions) 48 between the gate insulating films 30 and the base regions 20. The p-type impurity concentration of the p⁻-type channel regions 48 is lower than the p-type impurity concentration of the base regions 20.

The semiconductor device manufacturing method according to the present embodiment further includes an ion implantation process for threshold voltage adjustment after the formation of the base regions 20 and before the formation of the gate insulating films 30 in the manufacturing method according to the first embodiment. For example, ions of phosphorus (P) or arsenic (As), which are n-type impurities, are implanted into the surfaces of the base regions 20.

From the viewpoint of improving the controllability of threshold voltage adjustment, the p-type impurity concentration of the p-type base regions (third semiconductor layers) 20 is desirably lower than the p-type impurity concentration of the p-type regions 16.

According to the method of manufacturing the MOSFET 300 of the third embodiment, the effects as those of the first embodiment are obtained. Moreover, the method includes the ion implantation process for threshold voltage adjustment, such that the impurity profile of the base regions 20 is determinable independently of the threshold voltage. Hence, a semiconductor device is achieved with further improved properties over those of the first embodiment.

### Fourth Embodiment

A method of manufacturing a semiconductor device according to a fourth embodiment is the same as that of the third embodiment except that n⁻-type channel regions are formed. Hence, the details overlapping those of the third embodiment are not described redundantly.

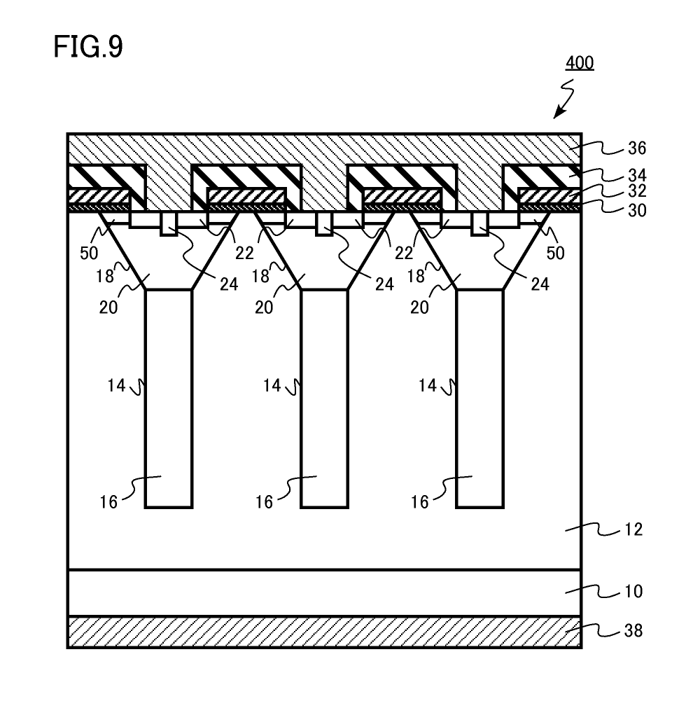

FIG. 9 is a schematic cross-sectional view of a semiconductor device to be manufactured by the semiconductor device manufacturing method according to the fourth embodiment. A MOSFET 400 of the fourth embodiment includes n⁻-type channel regions (second semiconductor regions) 50 between the gate insulating films 30 and the base regions 20.

The semiconductor device manufacturing method according to the fourth embodiment further includes an ion implantation process for threshold voltage adjustment after the formation of the base regions 20 and before the formation of the gate insulating films 30 in the manufacturing method according to the first embodiment. For example, ions of phosphorus (P) or arsenic (As), which are n-type impurities, are implanted into the surfaces of the base regions 20.

From the viewpoint of improving the controllability of threshold voltage adjustment, the p-type impurity concentration of the p-type base regions (third semiconductor layers) 20 is desirably lower than the p-type impurity concentration of the p-type regions 16.

According to the method of manufacturing the MOSFET 400 of the fourth embodiment, the same effects as those of the first embodiment are obtained. Moreover, as in the third embodiment, the method includes the ion implantation process for threshold voltage adjustment, such that the impurity profile of the base regions 20 is determinable independently of the threshold voltage. Hence, a semiconductor device is achieved with further improved properties over those of the first embodiment.

### Fifth Embodiment

A method of manufacturing a semiconductor device according to a fifth embodiment is the same as that of the first embodiment except that the SJ structure is completed by iteration of the epitaxial growth method of n-type semiconductor layers and ion implantation of p-type impurities into the n-type semiconductor layers. Hence, the details overlapping those of the first embodiment are not described redundantly.

According to the semiconductor device manufacturing method according to the fifth embodiment, the SJ structure is completed by repeating a plurality of times the epitaxial growth method of n-type semiconductor layers and partial ion implantation of p-type impurities into the n-type semiconductor layers. This method enables formation of the structure corresponding to FIG. 3 of the first embodiment. The processes after that are the same of those of the first embodiment.

According to the method of manufacturing a MOSFET of the fifth embodiment also, as in the first embodiment, reduction of breakdown voltage of the MOSFET is suppressed, and the controllability of breakdown voltage is improved. Further, increase in on-resistance of the MOSFET is suppressed, and the controllability of on-resistance is improved.

In the foregoing embodiments, description is given of examples in which the first conductivity type is n-type and the second conductivity type is p-type; however, the first conductivity type may be p-type, and the second conductivity type may be n-type.

Further, in the foregoing embodiments, description is given of exemplary MOSFETs with the SJ structure; however, embodiments of the present invention are applicable to other semiconductor devices such as insulated gate bipolar transistors (IGBTs) with an SJ structure.

Further, in the foregoing embodiments, description is given of an exemplary semiconductor material of monocrystalline silicon; however, embodiments of the present invention are applicable to other semiconductor materials with a diamond-type structure or a sphalerite-type structure, such as germanium, diamond, and gallium arsenide. In addition, embodiments of the present invention are applicable to other crystalline structures.

While certain embodiments have been described, these embodiments have been presented by way of example only, and are not intended to limit the scope of the inventions. Indeed, the semiconductor device manufacturing methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
forming a first trench in a first semiconductor layer of a first conductivity type;
forming a second semiconductor layer of a second conductivity type in the first trench by using an epitaxial growth method;
forming a second trench in the second semiconductor layer, the second trench having a smaller depth than the first trench;
forming a third semiconductor layer of the second conductivity type in the second trench by using the epitaxial growth method;
forming a gate insulating film on the third semiconductor layer;
forming a gate electrode on the gate insulating film; and
forming a first semiconductor region of the first conductivity type in the third semiconductor layer.

2. The method according to claim 1, wherein the first semiconductor region is shallower in depth than the third semiconductor layer.

3. The method according to claim 1, wherein the third semiconductor layer is lower in impurity concentration of the second conductivity type than the second semiconductor layer.

4. The method according to claim 1, wherein the second trench has a larger width than the first trench.

5. The method according to claim 1, further comprising polishing the second semiconductor layer before the forming of the second trench.

6. The method according to claim 1, wherein an inclination angle of a side surface of the second trench with respect to a film thickness direction of the first semiconductor layer is larger than an inclination angle of a side surface of the first trench with respect to the film thickness direction of the first semiconductor layer.

7. The method according to claim 1, wherein the second trench has a U shape.

8. The method according to claim 1, further comprising performing ion implantation of impurities of the first conductivity type into the third semiconductor layer to form a second semiconductor region after the forming of the third semiconductor layer and before the forming of the gate insulating film.

9. The method according to claim 8, wherein the second semiconductor region is of the first conductivity type.

10. The method according to claim 1, wherein the first semiconductor layer, the second semiconductor layer, and the third semiconductor layer are monocrystalline silicon.

11. A method of manufacturing a semiconductor device, the method comprising:
forming a structure having a first semiconductor layer of a first conductivity type and a second semiconductor layer of a second conductivity type alternately arranged therein;
forming a trench in the second semiconductor layer;
forming a third semiconductor layer of the second conductivity type in the trench by using an epitaxial growth method;
forming a gate insulating film on the third semiconductor layer;
forming a gate electrode on the gate insulating film; and
forming a semiconductor region of the first conductivity type in the third semiconductor layer.

12. The method according to claim 11, wherein the first semiconductor region is shallower in depth than the third semiconductor layer.

13. The method according to claim 11, wherein the third semiconductor layer is lower in impurity concentration of the second conductivity type than the second semiconductor layer.

14. The method according to claim 11, wherein the second trench has a U shape.

15. The method according to claim 11, further comprising performing ion implantation of impurities of the first conductivity type into the third semiconductor layer to form a second semiconductor region after the forming of the third semiconductor layer and before the forming of the gate insulating film.

16. The method according to claim 15, wherein the second semiconductor region is of the first conductivity type.

17. The method according to claim 11, wherein the first semiconductor layer, the second semiconductor layer, and the third semiconductor layer are monocrystalline silicon.
